(19) United States
(12) Patent Application Publication
(10) Pub. No.: US 2020/0203595 A1
(43) Pub. Date: Jun. 25, 2020

(54) CERAMIC PIEZOELECTRIC FIBER COMPOSITE MATERIAL AND SHOE HAVING THE SAME

(71) Applicant: INDUSTRIAL TECHNOLOGY RESEARCH INSTITUTE, Hsinchu (TW)

(72) Inventors: Min Yan DONG, Changhua County (TW); Chia-Hsin LIN, Hsinchu City (TW)

(73) Assignee: INDUSTRIAL TECHNOLOGY RESEARCH INSTITUTE, Hsinchu (TW)

(21) Appl. No.: 16/676,222

(22) Filed: Nov. 6, 2019

(30) Foreign Application Priority Data
Dec. 25, 2018 (TW) 107146991

(51) Int. Cl. H01L 41/187; A43B 3/00; C04B 35/50

(52) U.S. Cl. CPC H01L 41/1875; C04B 2235/3227; C04B 35/50; A43B 3/0015

(57) ABSTRACT

A piezoelectric composite material includes a cross-linker and a plurality of ceramic fibers disposed in the cross-linker. The ceramic fibers include ABO₃ oxide. A-site represents PbₓLa_{y} containing lead (Pb) and lanthanum (La). In PbₓLa_{y}, x ranges from 0.920 to 0.950, and y ranges from 0.050 to 0.080.

### CROSS-REFERENCE TO RELATED APPLICATIONS

This non-provisional application claims priority under 35 U.S.C. § 119(a) on Patent Application No(s). 107146991 filed in Taiwan R.O.C on Dec. 25, 2018, the entire contents of which are hereby incorporated by reference.

### BACKGROUND

### 1. Technical Field

This present disclosure relates to a piezoelectric composite material including ceramic fiber and a shoe including the piezoelectric composite material.

### 2. Related Art

With the development of technology, the demand for wearable devices is gradually increasing, and people have more requirements on the functions of wearable devices. At present, the wearable devices on the market often need additional power supply module (such as battery) to achieve the functions required by consumers, but the additional power supply is unfavorable for portability.

As to some wearable devices, the power supply module is replaced with piezoelectric material to supply electric power. For example, a soft composite containing piezoelectric material is disposed on the bottom of a shoe sole. When a user wearing the shoe is walking or running, the piezoelectric material in the soft composite generates pulsed current according to the stress difference caused by body weight. The pulsed current can be used to store electricity for self-power generating function and produce physiological activity signals.

### SUMMARY

According to one aspect of the present disclosure, a piezoelectric composite material includes a cross-linker and a plurality of ceramic fibers disposed in the cross-linker. The ceramic fibers include ABO₃ oxide. A-site represents PbₓLa_{y} containing lead (Pb) and lanthanum (La), and the following conditions are satisfied:

0.920≤x≤0.950; and

0.050≤y≤0.080.

According to another aspect of the present disclosure, a shoe includes the aforementioned piezoelectric composite material.

According to still another aspect of the present disclosure, a ceramic fiber includes ABO₃ oxide. A-site represents PbₓLa_{y} containing lead (Pb) and lanthanum (La), and the following conditions are satisfied:

0.920≤x≤0.950; and

0.050≤y≤0.080.

### BRIEF DESCRIPTION OF THE DRAWINGS

FIG. 1 is a perspective view of a piezoelectric composite material according to one embodiment of the present disclosure;

FIG. 2 is a schematic view showing measurement of piezoelectric coefficient of ceramic fibers in the piezoelectric composite material of FIG. 1;

FIG. 3 is a perspective view of a piezoelectric composite material according to another embodiment of the present disclosure; and

FIG. 4 is a perspective view of a shoe according to still another embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

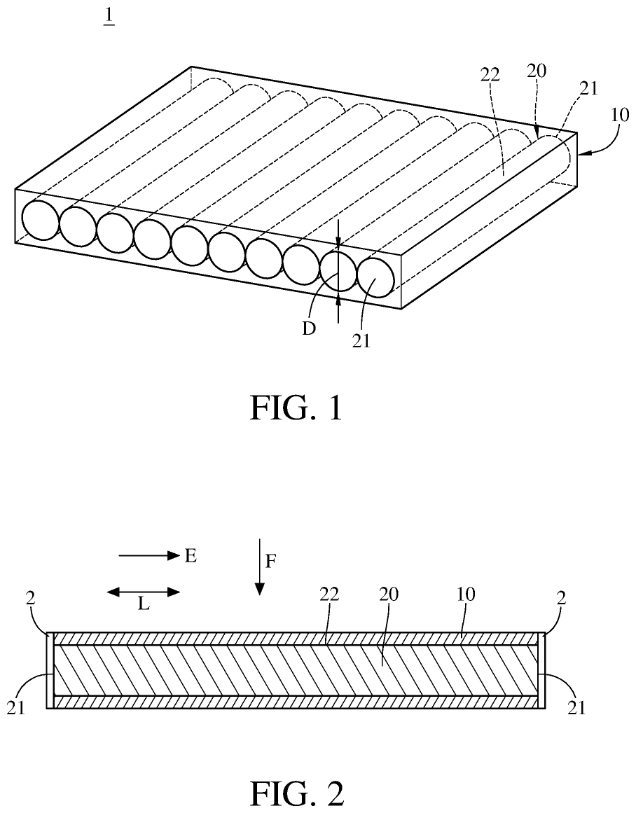

According to one embodiment of the present disclosure, a piezoelectric composite material includes a cross-linker and a plurality of ceramic fibers. Please refer to FIG. 1 representing is a perspective view of a piezoelectric composite material according to one embodiment of the present disclosure. According to this embodiment, the piezoelectric composite material 1 includes a cross-linker 10 and a plurality of ceramic fibers 20. Each ceramic fiber 20 has different two ends exposing to outside from the cross-linker 10. At least some of the ceramic fibers 20 contact each other and are arranged periodically.

The cross-linker 10, for example but not limited to, is made of polymer such as Polyethylene, polyvinyl chloride, chlorinated polyethylene, polyethylene acetate, polystyrene acrylic acid, epoxy resin, polyphthalate diallyl ester and the like. It is noted that the present disclosure is not limited by the aforementioned cross-linker.

The ceramic fiber 20 includes ABO₃ (perovskite) oxide, and the PZT (Lead zirconate titanate) structure is composed of ABO₃ oxide. In this embodiment, A-site represents divalent metal ion(s), and B-site represents quadrivalent metal ion or a group of ions with quadrivalence. In one embodiment, A-site contains lead (Pb) and lanthanum (La), and B-site is selected from the group consisting of titanium (Ti), zirconium (Zr), Manganese (Mn), cobalt (Co), niobium (Nb), Iron (Fe), zinc (Zn), Magnesium (Mg), Yttrium (Y), tin (Sn), nickel (Ni), tungsten (W) and combination thereof. It is noted that the present disclosure is not limited by the aforementioned B-site ions.

With regard to ABO₃ oxide in the present disclosure, A-site represents PbₓLa_{y}, and the following conditions are satisfied: 0.920≤x≤0.950; and 0.050≤y≤0.080. Therefore, ABO₃ oxide is favorable for the ceramic fiber 20 enjoying good piezoelectricity. In some embodiments, in PbₓLa_{y}, x is equal to 0.950 and y is equal to 0.050.

As shown in FIG. 1, according to one embodiment of the present disclosure, the diameter D of the ceramic fiber 20 is from 0.20 millimeter (mm) to 1.0 mm. Therefore, it is favorable for the ceramic fiber 20 meet the requirements of proper flexibility and high piezoelectricity. In some embodiments, the diameter D of the ceramic fiber 20 is from 0.30 mm to 0.50 mm.

According to one embodiment of the present disclosure, the fiber volume ratio in the piezoelectric composite material 1 is from 60.0% to 90.0%; that is, 60.0% to 90.0% of ceramic fibers 20 are existed in the entire volume of the piezoelectric composite material 1. Therefore, piezoelectric composite material 1 It is favorable for the piezoelectric composite material 1 having good sensitivity such that the piezoelectric composite material 1 can generate electricity by less stress, and thereby suitable to be applied in wearable products. In some embodiments, the fiber volume ratio in the piezoelectric composite material 1 is from 80.0% to 90.0%.

According to one embodiment of the present disclosure, the piezoelectric coefficient d33 of the ceramic fiber 20 is greater than or equal to 700.0 pC/N. Please further refer to FIG. 2 which is a schematic view showing measurement of piezoelectric coefficient of ceramic fibers in the piezoelectric composite material of FIG. 1. Two eletrodes 2 are disposed on opposite sides of the piezoelectric composite material 1, respectively, and the electrode 2 can be conductive silver glue. Opposite end facets 21 of the ceramic fiber 20 contact the eletrodes 2, respectively. When there is an electric field E in the length direction L between the electrodes 2, the ceramic fiber 2 deforms in the length direction L. The volume change of the ceramic fiber in the length direction L caused by the electric field E is known as the piezoelectric coefficient d33. In some embodiments, the piezoelectric coefficient d33 of the ceramic fiber 20 is from 719.0 pC/N to 807.0 pC/N.

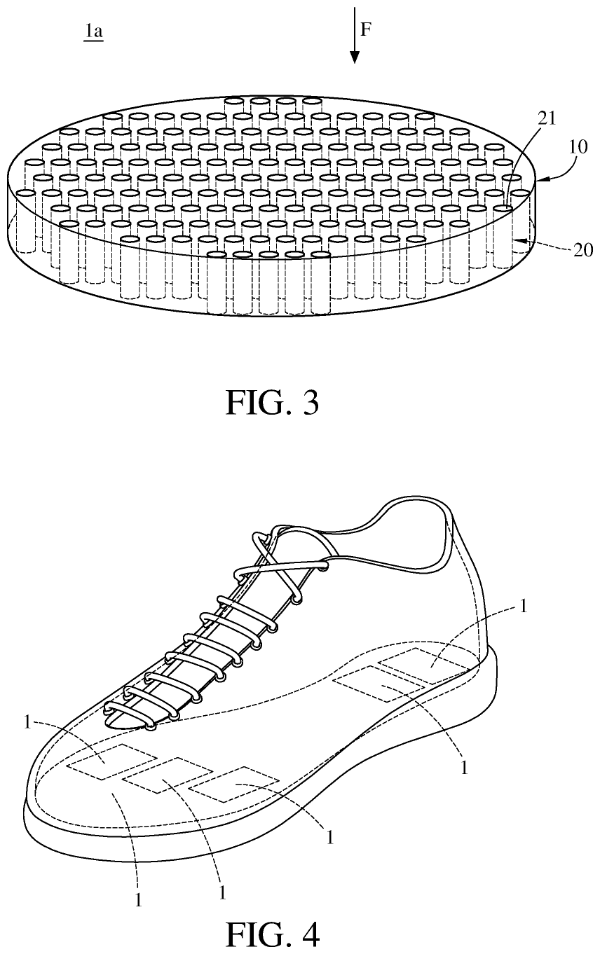

As shown in FIG. 1, the ceramic fibers 20 are horizontally arranged in the cross-linker 10. As a result, when the piezoelectric composite material 1 is applied to electricity production, a force F is applied in a direction orthogonal to the lateral surface of the ceramic fiber 20 to make the ceramic fibers 20 have obvious deformation, thereby enhancing the sensitivity of the piezoelectric composite material 1 as well as obtaining high electricity production efficiency. It is noted that the present disclosure is not limited by the arrangement of ceramic fibers. FIG. 3 is a perspective view of a piezoelectric composite material according to another embodiment of the present disclosure. A piezoelectric composite material 1a includes a plurality of ceramic fibers 20 which are vertically arranged in the cross-linker 10, such that the force F is applied on the end facet 21 of the ceramic fiber 20.

According to one embodiment of the present disclosure, piezoelectric composite material is applicable to shoe making. FIG. 4 is a perspective view of a shoe according to still another embodiment of the present disclosure. The piezoelectric composite material 1 can be in a form of round patch or rectangular patch with 10-12 square centimeters of area, and the patch is attached to a shoe sole. It is noted that the present disclosure is not limited by the size and shape of the piezoelectric composite material 1. When a user wearing the shoe walks or runs, the user's weight is applied on the piezoelectric composite material 1 to deform the ceramic fibers 20, such that the ceramic fibers 20 generate electric current. The electric current generated by the ceramic fibers 20 can be used as electric power supplied to other electronic components (not shown in the drawings) mounted to the shoe, or used as electric signal received by external electronic device (such as a computer or mobile phone) to analyze foot pressure distribution.

In the following paragraphs, several specific embodiments and comparative examples are provided to illustrate the technical effects of the piezoelectric composite material according to the present disclosure.

### Embodiment 1

A piezoelectric composite material with a configuration in FIG. 1 is provided. The piezoelectric composite material includes epoxy resin (cross-linker) and ceramic fibers. The ceramic fiber includes Pb_{0.95}La_{0.05}TiO₃. The diameter of the ceramic fiber is 0.4 mm, and the fiber volume ratio in the piezoelectric composite material is 80.0%.

### Embodiment 2

A piezoelectric composite material with a configuration in FIG. 1 is provided. The piezoelectric composite material includes epoxy resin (cross-linker) and ceramic fibers. The ceramic fiber includes Pb_{0.93}La_{0.07}TiO₃. The diameter of the ceramic fiber is 0.4 mm, and the fiber volume ratio in the piezoelectric composite material is 80.0%.

### Embodiment 3

A piezoelectric composite material with a configuration in FIG. 1 is provided. The piezoelectric composite material includes epoxy resin (cross-linker) and ceramic fibers. The ceramic fiber includes Pb_{0.92}La_{0.08}TiO₃. The diameter of the ceramic fiber is 0.4 mm, and the fiber volume ratio in the piezoelectric composite material is 80.0%.

### Comparative Example 1

A piezoelectric composite material with a configuration in FIG. 1 is provided. The piezoelectric composite material includes epoxy resin (cross-linker) and ceramic fibers. The ceramic fiber includes Pb_{0.96}La_{0.04}TiO₃. The diameter of the ceramic fiber is 0.4 mm, and the fiber volume ratio in the piezoelectric composite material is 80.0%.

### Comparative Example 2

A piezoelectric composite material with a configuration in FIG. 1 is provided. The piezoelectric composite material includes epoxy resin (cross-linker) and ceramic fibers. The ceramic fiber includes Pb_{0.97}La_{0.03}TiO₃. The diameter of the ceramic fiber is 0.4 mm, and the fiber volume ratio in the piezoelectric composite material is 80.0%.

### Comparative Example 3

A piezoelectric composite material with a configuration in FIG. 1 is provided. The piezoelectric composite material includes epoxy resin (cross-linker) and ceramic fibers. The ceramic fiber includes Pb_{0.91}La_{0.09}TiO₃. The diameter of the ceramic fiber is 0.4 mm, and the fiber volume ratio in the piezoelectric composite material is 80.0%.

The detailed piezoelectricity of the embodiments and examples is shown in Table I below.

TABLE I

| | | | Electro- |
|---|---|---|---|
| | | | mechanical |
| | | Piezoelectric | coupling |
| | | coefficient | coefficient |
| | ABO₃ oxide | d33 | k33 |
| Embodiment 1 | (Pb_{0.95}La_{0.05})TiO₃ | 719 pC/N | 3794 |
| Embodiment 2 | (Pb_{0.93}La_{0.07})TiO₃ | 807 pC/N | 4307 |
| Embodiment 3 | (Pb_{0.92}La_{0.08})TiO₃ | 741 pC/N | 4210 |
| Example 1 | (Pb_{0.96}La_{0.04})TiO₃ | 487 pC/N | 2539 |
| Example 2 | (Pb_{0.97}La_{0.03})TiO₃ | 461 pC/N | 2344 |
| Example 3 | (Pb_{0.91}La_{0.09})TiO₃ | 556 pC/N | 3163 |

Referring to TABLE I, when A-site in ABO₃ oxide satisfies the conditions of 0.920≤x≤0.950 and 0.050≤y≤0.080, the piezoelectric coefficient d33 of the ceramic fiber is greater than or equal to 700 pC/N, and such high piezoelectric coefficient d33 provides good piezoelectricity. Moreover, the ceramic fiber has much higher piezoelectric coefficient d33 when x is equal to 0.930, and y is equal to 0.070.

A mass (force) is applied on the piezoelectric composite material of embodiment 1, and the voltage generated by the piezoelectric composite material is measured so as to confirm a relationship between the applied stress and the generated voltage. The detailed result is shown in Table II below.

TABLE II

| Mass | Stress | Voltage |
|---|---|---|
| (kg) | (kg/cm²) | (V) |
| 5 | 0.60 | 0.09 |
| 10 | 1.21 | 2 |
| 15 | 1.81 | 3.3 |
| 20 | 2.41 | 3.6 |
| 25 | 3.02 | 3.8 |
| 30 | 3.62 | 4 |
| 40 | 4.23 | 4.2 |
| 45 | 4.83 | 4.3 |

According to the disclosure, the ceramic fibers in the piezoelectric composite material include ABO₃ oxide. A-site represents PbₓLa_{y} containing Pb and La, and the following conditions are satisfied: 0.920≤x≤0.950; and 0.050≤y≤0.080. Therefore, ABO₃ oxide with specific composition is favorable for the ceramic fibers enjoying good piezoelectricity, that is, a higher piezoelectric coefficient d33.

Furthermore, since higher piezoelectric coefficient d33, the ceramic fiber is sensitive to less stress even though it has small size, such that the ceramic fiber is applicable to wearable products such as shoe.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A piezoelectric composite material, comprising:
a cross-linker; and
a plurality of ceramic fibers disposed in the cross-linker, the plurality of ceramic fibers comprising ABO₃ oxide, wherein A-site represents PbₓLa_{y} containing lead (Pb) and lanthanum (La), and the following conditions are satisfied:
0.920≤x≤0.950; and
0.050≤y≤0.080.

2. The piezoelectric composite material according to claim 1, wherein x is equal to 0.930, and y is equal to 0.070.

3. The piezoelectric composite material according to claim 1, wherein a diameter of each of the plurality of ceramic fibers is from 0.20 mm to 1.0 mm.

4. The piezoelectric composite material according to claim 3, wherein the diameter of each of the plurality of ceramic fibers is from 0.30 mm to 0.50 mm.

5. The piezoelectric composite material according to claim 1, wherein a fiber volume ratio in the piezoelectric composite material is from 60.0% to 90.0%.

6. The piezoelectric composite material according to claim 5, wherein the fiber volume ratio in the piezoelectric composite material is from 80.0% to 90.0%.

7. The piezoelectric composite material according to claim 1, wherein piezoelectric coefficient d33 of each of the plurality of ceramic fibers is greater than or equal to 700.0 pC/N.

8. The piezoelectric composite material according to claim 7, wherein piezoelectric coefficient d33 of each of the plurality of ceramic fibers is from 719.0 pC/N to 807.0 pC/N.

9. The piezoelectric composite material according to claim 1, wherein different two ends of piezoelectric coefficient d33 of each of the plurality of ceramic fibers expose to outside from the cross-linker.

10. The piezoelectric composite material according to claim 1, wherein at least some of the plurality of ceramic fibers contact each other.

11. A shoe, comprising the piezoelectric composite material according to claim 1.

12. A ceramic fiber, comprising ABO₃ oxide, wherein A-site represents PbₓLa_{y} containing lead (Pb) and lanthanum (La), and the following conditions are satisfied:
0.920≤x≤0.950; and
0.050≤y≤0.080.

13. The ceramic fiber according to claim 12, wherein x is equal to 0.930, and y is equal to 0.070.

14. The ceramic fiber according to claim 12, wherein a diameter of the ceramic fiber is from 0.20 mm to 1.0 mm.

15. The ceramic fiber according to claim 12, wherein piezoelectric coefficient d33 of the ceramic fiber is greater than or equal to 700.0 pC/N.
